(19) United States
(12) Patent Application Publication
(10) Pub. No.: US 2024/0395462 A1
(43) Pub. Date: Nov. 28, 2024

(54) MULTILAYER CERAMIC CAPACITOR AND METHOD OF MOUNTING MULTILAYER CERAMIC CAPACITOR

(71) Applicant: Murata Manufacturing Co., Ltd., Nagaokakyo-shi (JP)

(72) Inventors: Hiroyuki AOYAMA, Nagaokakyo-shi (JP); Ryota KARAYA, Nagaokakyo-shi (JP)

(21) Appl. No.: 18/791,579

(22) Filed: Aug. 1, 2024

Related U.S. Application Data
(63) Continuation of application No. PCT/JP2023/015660, filed on Apr. 19, 2023.

(30) Foreign Application Priority Data
Apr. 27, 2022 (JP) 2022-073625
Mar. 17, 2023 (JP) 2023-043446

(51) Int. Cl. H01G 4/232; H01G 4/012; H01G 4/30

(52) U.S. Cl. CPC H01G 4/232; H01G 4/012; H01G 4/30

(57) ABSTRACT

A multilayer ceramic capacitor includes a multilayer body including dielectric layers and internal electrode layers alternately laminated, main surfaces, side surfaces, and end surfaces, and external electrodes on the end surfaces and each including an end surface portion on the end surface where the external electrode is provided, main surface portions respectively extending on the main surfaces between the end surfaces, and side surface portions respectively extending on the side surfaces between the end surfaces. Each main surface portion includes a longest portion longer than a remainder of the main surface portion. When the multilayer ceramic capacitor is viewed from the main surface, the longest portion is located on a region that does not overlap with a region in which the internal electrode layers are located.

### CROSS REFERENCE TO RELATED APPLICATIONS

This application claims the benefit of priority to Japanese Patent Application No. 2022-073625 filed on Apr. 27, 2022 and Japanese Patent Application No. 2023-043446 filed on Mar. 17, 2023, and is a Continuation Application of PCT Application No. PCT/JP2023/015660 filed on Apr. 19, 2023. The entire contents of each application are hereby incorporated herein by reference.

### BACKGROUND OF THE INVENTION

### 1. Field of the Invention

The present invention relates to multilayer ceramic capacitors and methods of mounting the multilayer ceramic capacitors.

### 2. Description of the Related Art

A multilayer ceramic capacitor includes a multilayer body and external electrodes disposed on both end surfaces of the multilayer body. The multilayer body includes an inner layer portion in which dielectric layers and internal electrode layers are laminated in a lamination direction, outer layer portions disposed on both sides of the inner layer portions that are adjacent to main surfaces, and side margin portions disposed on both side surfaces of the inner layer portion.

In recent years, multilayer ceramic capacitors have been reduced in size and increased in capacitance, and accordingly, have very thin outer layer portions and very thin side margin portions (see Japanese Unexamined Patent Application, Publication No. 2021-86893).

### SUMMARY OF THE INVENTION

When a bending force is applied to a board on which the multilayer ceramic capacitor having such thin outer layer portions and thin side margin portions is mounted, the multilayer ceramic capacitor is likely to bend, particularly at its main surfaces, together with the board.

On the other hand, each external electrode extends not only on the end surface of the multilayer body but also to the main surfaces and the side surfaces. The external electrode includes portions extending on the main surfaces from one end surface toward the other end surface. In a conventional configuration, each of these portions has its largest length at a portion at the center in the width direction and each has a shape that is convex toward the other end surface.

When the multilayer ceramic capacitor having the conventional configuration is bent, stress is likely to concentrate on the convex portion. The convex portion then presses the thin outer layer portion to cause a crack there. The crack may penetrate the outer layer portion to reach the internal electrodes in the inner layer portion, and moisture may infiltrate through the crack to cause a defect such as a short circuit.

Example embodiments of the present invention provide multilayer ceramic capacitors that are resistant to cracking and methods of mounting such multilayer ceramic capacitors.

An example embodiment of the present invention provides a multilayer ceramic capacitor including a multilayer body including dielectric layers and internal electrode layers alternately laminated, and including main surfaces on both sides in a lamination direction, side surfaces on both sides in a width direction that is orthogonal to the lamination direction, and end surfaces on both sides in a length direction that intersects with the lamination direction and the width direction, and external electrodes respectively provided on the end surfaces and each including an end surface portion on the end surface where the external electrode is provided, main surface portions respectively extending on the main surfaces in the length direction from the end surface toward an other end surface, and side surface portions respectively extending on the side surfaces in the length direction from the end surface toward the other end surface. Each of the main surface portions includes a longest portion that is longer in the length direction than a remainder of the main surface portion and, when the multilayer ceramic capacitor is viewed from the main surface, the longest portion is located on a region that does not overlap with a region in which the internal electrode layers are located.

Another example embodiment of the present invention provides a method of mounting the multilayer ceramic capacitor according the example embodiment described above, the method including placing the multilayer ceramic capacitor such that one of the main surfaces defines and functions as a mounting surface.

The example embodiments of the present invention provide multilayer ceramic capacitors that are resistant to cracking and methods of mounting such multilayer ceramic capacitors.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic perspective view of a multilayer ceramic capacitor 1 according to a first example embodiment of the present invention.

FIG. 2 is a cross-sectional view of the multilayer ceramic capacitor 1, taken along line II-II in FIG. 1.

FIG. 3 is a cross-sectional view of the multilayer ceramic capacitor 1, taken along line III-III in FIG. 1.

FIG. 4 illustrates an example of an enlarged image of a cross section where an inner layer portion 11 is exposed.

FIG. 5 is a front view of the multilayer ceramic capacitor 1 of the first example embodiment of the present invention, as viewed from a first main surface A1 in a lamination direction T.

FIG. 6 is a flowchart illustrating a method of manufacturing the multilayer ceramic capacitor 1.

FIG. 7 is a diagram illustrating a process for forming an external electrode 3.

FIG. 8 is a front view of a multilayer ceramic capacitor 101 of a second example embodiment of the present invention, as viewed from a first main surface A1 in a lamination direction T.

### DETAILED DESCRIPTION OF THE EXAMPLE EMBODIMENTS

### First Example Embodiment

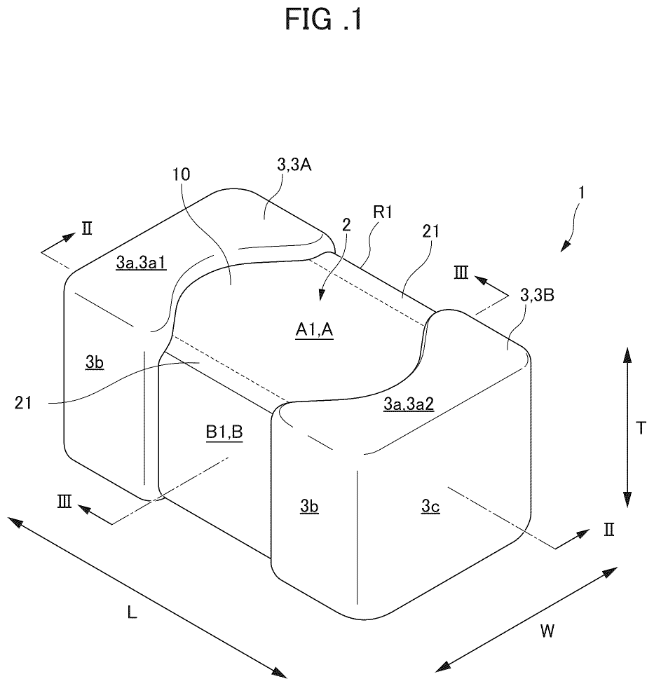

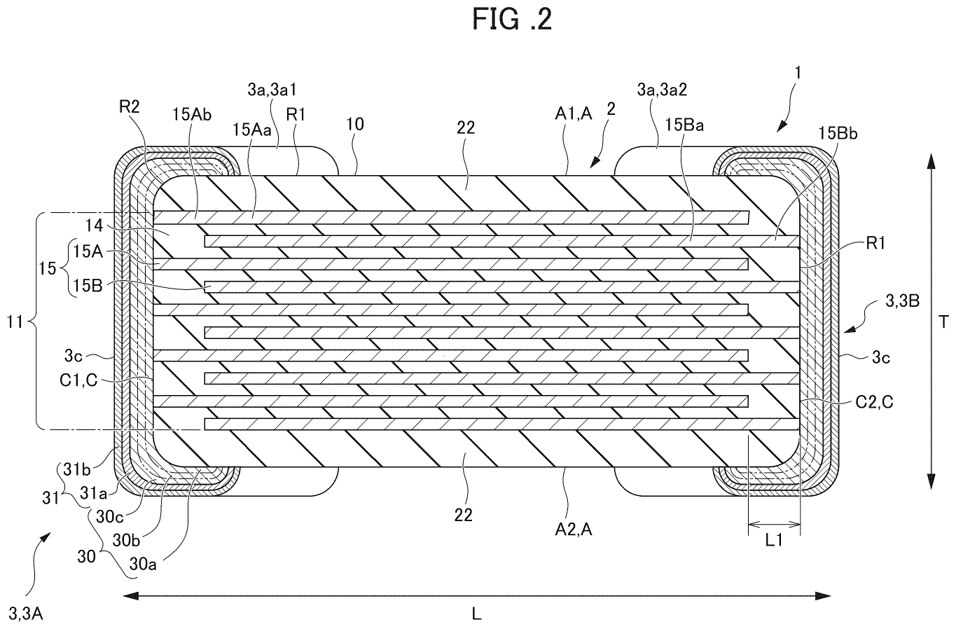

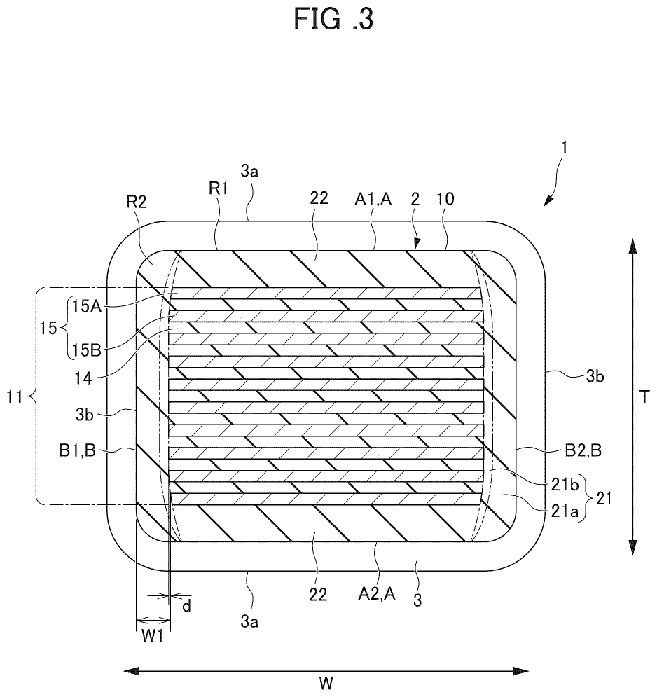

A multilayer ceramic capacitor 1 according to a first example embodiment of the present invention and a method of mounting the multilayer ceramic capacitor 1 on a board will be described below. FIG. 1 is a schematic perspective view of the multilayer ceramic capacitor 1 according to the first example embodiment. FIG. 2 is a cross-sectional view of the multilayer ceramic capacitor 1, taken along line II-II in FIG. 1. FIG. 3 is a cross-sectional view of the multilayer ceramic capacitor 1, taken along taken along line III-III in FIG. 1.

The multilayer ceramic capacitor 1 has a substantially rectangular parallelepiped shape, and includes a multilayer body 2 including an inner layer portion 11 in which dielectric layers 14 and internal electrode layers 15 are laminated, and a pair of external electrodes 3 provided at both ends of the multilayer body 2.

In the following description, the orientation of the multilayer ceramic capacitor 1 is described using the following terms. A direction in which the dielectric layers 14 and the internal electrode layers 15 are laminated is referred to as a lamination direction T. A direction in which the external electrodes 3 on the multilayer ceramic capacitor 1 are located is referred to as a length direction L. A direction intersecting with both the lamination direction T and the length direction L is referred to as a width direction W. In the present example embodiment, the width direction W is orthogonal to both the length direction L and the lamination direction T. The multilayer ceramic capacitor 1 of the present example embodiment has a larger dimension in the length direction L than in the width direction W and the lamination direction T, but the present invention is not limited to this configuration. The dimension in the length direction L does not have to be longer than those in the width direction W and the lamination direction T.

In the following description, among the six outer surfaces of the multilayer body 2, a pair of outer surfaces on both sides in the lamination direction T are referred to as a first main surface A1 and a second main surface A2, a pair of outer surfaces on both sides in the width direction W are referred to as a first side surface B1 and a second side surface B2, and a pair of outer surfaces on both sides in the length direction L are referred to as a first end surface C1 and a second end surface C2. The first main surface A1 and the second main surface A2 are collectively referred to as a main surface(s) A when it is unnecessary to particularly distinguish from each other. The first side surface B1 and the second side surface B2 are collectively referred to as a side surface(s) B when it is unnecessary to particularly distinguish from each other. The first end surface C1 and the second end surface C2 are collectively referred to as an end surface(s) C when it is unnecessary to particularly distinguish from each other.

### Dimensions of Multilayer Ceramic Capacitor 1

The dimensions of the multilayer ceramic capacitor 1 are preferably, for example, about 0.2 mm or greater and about 2.0 mm or less in the length direction L, about 0.1 mm or greater and about 1.0 mm or less in the width direction W, and about 0.1 mm or greater and about 0.5 mm or less in the lamination direction T.

Specifically, the multilayer ceramic capacitor 1 has a size of, for example, type 01005, 0201, 0402, or 0603 of the EIA standards. In the type 01005, L≈0.40 mm, W≈0.20 mm, and T≈0.13 mm, for example. In the type 0201, L≈0.60 mm, W≈0.30 mm, and T≈0.23 mm, for example. In the type 0402, L≈1.00 mm, W≈0.50 mm, and T≈0.35 mm, for example. In the type 0603, L≈1.60 mm, W≈0.80 mm, and T≈0.45 mm, for example. The foregoing values are not exact values and include tolerances.

### Multilayer Body 2

The multilayer body 2 has a substantially rectangular parallelepiped shape, and it is preferable that the ridges R1 and the corners R2 of the multilayer body 2 are rounded. Each ridge R1 is where two surfaces of the multilayer body 2, that is, the main surface A and the side surface B, the main surface A and the end surface C, or the side surface B and the end surface C meet each other. Each corner R2 is where the main surface A, the side surface B, and the end surface C meet one another.

The multilayer body 2 includes a multilayer chip 10 and side margin portions 21. The multilayer chip 10 includes the inner layer portion 11 in which the dielectric layers 14 and the internal electrode layers 15 are laminated, and two outer layer portions 22 disposed on both sides of the inner layer portion 11 in the lamination direction T. The side margin portions 21 are disposed on both sides of the multilayer chip 10 in the width direction W.

### Internal Electrode Layer 15

The internal electrode layers 15 include a plurality of first internal electrode layers 15A and a plurality of second internal electrode layers 15B. The first internal electrode layers 15A and the second internal electrode layers 15B are alternately arranged. The first internal electrode layer 15A and the second internal electrode layer 15B are collectively referred to as the internal electrode layer(s) 15 when it is unnecessary to particularly distinguish from each other.

Each first internal electrode layer 15A includes a first counter portion 15Aa opposed to the second internal electrode layers 15B, and a first lead-out portion 15Ab extending from the first counter portion 15Aa to be led out to the first end surface C1. An end of each first lead-out portion 15Ab is exposed at the first end surface C1 and is electrically connected to a first external electrode 3A, which will be described later.

Each second internal electrode layer 15B includes a second counter portion 15Ba opposed to the first internal electrode layers 15A, and a second lead-out portion 15Bb extending from the second counter portion 15Ba to be led out to the second end surface C2. An end of each second lead-out portion 15Bb is exposed at the second end surface C2 and is electrically connected to a second external electrode 3B, which will be described later.

Electric charge is accumulated between the first counter portion 15Aa of the first internal electrode layer 15A and the second counter portion 15Ba of the second internal electrode layer 15B, which are opposed to each other with the dielectric layer 14 interposed therebetween, whereby the internal electrode layers 15 fulfill the function as a capacitor.

The first counter portion 15Aa and the second counter portion 15Ba are collectively referred to as the counter portion(s) 15a when it is unnecessary to particularly distinguish from each other. The first lead-out portion 15Ab and the second lead-out portion 15Bb are collectively referred to as the lead-out portion(s) 15b when it is unnecessary to particularly distinguish from each other.

As illustrated in FIG. 3, two adjacent internal electrodes, i.e., one first internal electrode layers 15A and one second internal electrode layers 15B that are vertically adjacent to each other in the lamination direction T have widthwise ends with a positional deviation d in the width direction W, and the positional deviation d is about 5 μm or less, for example.

That is, the widthwise ends of each first internal electrode layer 15A and the second internal electrode layer 15B that is vertically adjacent to the first internal electrode layer 15A in the lamination direction T are substantially at the same position in the width direction W, and are substantially aligned with each other in the lamination direction T.

Referring to FIG. 2, Li denotes a distance from the counter portion 15a to the end surface C, that is, a length (L gap) of the lead-out portion 15b, and Li is preferably about 10 μm or greater and about 30 μm or less, for example. The number of internal electrode layers 15 is preferably 100 or more and 1000 or less, for example.

The thickness of the internal electrode layer 15 is preferably about 0.35 μm or greater and about 0.42 μm or less, for example. The thickness of the internal electrode layer 15 is measured as follows, for example. First, a LT cross section that passes through a center of the multilayer ceramic capacitor 1 and extends in the length direction L and the lamination direction T is polished so that the inner layer portion 11 is exposed. If necessary, the exposed cross section is etched to remove portions of the layers stretched due to the polishing.

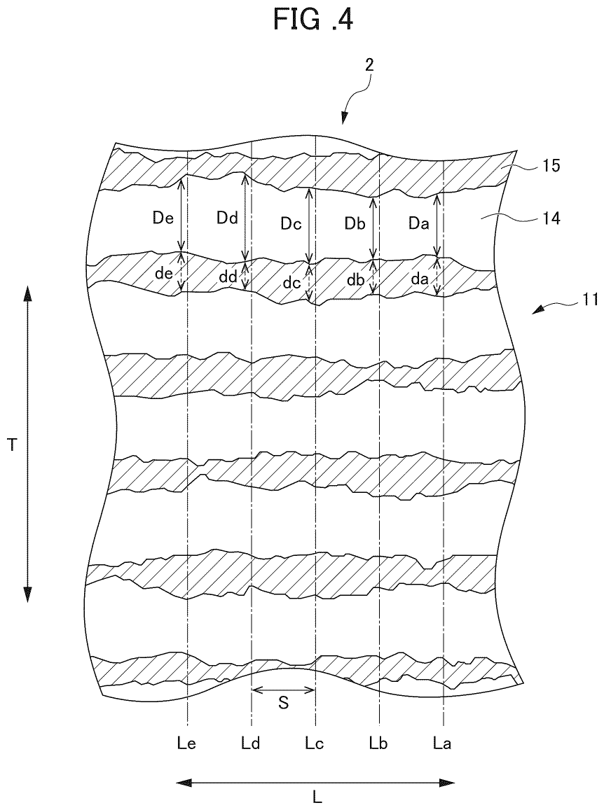

FIG. 4 illustrates an example of an enlarged image of the cross section where the inner layer portion 11 is exposed. In the enlarged image, for example, a plurality of equidistant straight lines La, Lb, Lc, Ld, and Le extending in the lamination direction T are drawn with a pitch S. The pitch S is preferably about 5 to 10 times the thickness of the internal electrode layer 15 to be measured. For example, in the case of measuring the internal electrode layer 15 having a thickness of about 1 μm, the pitch S is set to about 5 μm.

Next, thicknesses da, db, dc, dd, and de of the internal electrode layer 15 are measured on the five straight lines La, Lb, Lc, Ld, and Le, respectively. However, in a case where the internal electrode layer 15 is absent on the straight lines La, Lb, Lc, Ld, and Le and the dielectric layers 14 sandwiching the internal electrode layer 15 are in contact with each other, or in a case where the enlarged view of the measurement position is unclear, new straight lines are drawn to measure the thickness of the internal electrode layers 15.

In a case where the number of laminated internal electrode layers 15 is less than 5, the thicknesses of all the internal electrode layers 15 are measured by the above-described method, and the average value thereof is defined as the average thickness of the plurality of internal electrode layers 15.

The internal electrode layers 15 contain, for example, a metal such as Ni, Cu, Ag, Pd, a Ag—Pd alloy, or Au. The internal electrode layers 15 may further include dielectric particles based on the same composition as the ceramic included in the dielectric layers 14.

Sn may be disposed at the interface between the internal electrode layer 15 and the dielectric layer 14. Sn may be disposed in the form of a layer or may be scattered. Sn may be solid-solved in the internal electrode layers 15, or may be solid-solved in dielectric grains in the dielectric layers 14.

### Dielectric Layer 14

The dielectric layers 14 are each made of a dielectric material an example of which is a dielectric ceramic including a component such as BaTiO₃, CaTiO₃, SrTiO₃, or CaZrO₃. The dielectric material may contain, in addition to the above component, a component such as a Mn compound, a Fe compound, a Cr compound, a Co compound, or a Ni compound in an amount smaller than that of the main component.

The sum of the number of dielectric layers 14 and the number of outer layer portions 22 is preferably 100 or more and 1000 or less, for example.

The thickness of each dielectric layer 14 is preferably about 0.35 μm or greater and about 0.45 μm or less, for example. The thickness of the dielectric layer 14 can also be determined by measuring and averaging thicknesses Da, Db, Dc, Dd, and De of the dielectric layers 14 on five straight lines La, Lb, Lc, Ld, and Le, respectively, similarly to the above-described measurement of the thickness of the internal electrode layer 15.

### Outer Layer Portion 22

The outer layer portions 22 include the dielectric layers 14 disposed on the sides of the inner layer portion 11 that are adjacent to the main surfaces A. The thickness of each outer layer portion 22 is preferably about 10 μm or greater and about 30 μm or less, for example.

### Side Margin Portion 21

The side margin portions 21 are disposed on both surfaces, which are adjacent to the side surfaces B, of the multilayer chip 10 that includes the outer layer portions 22 and the inner layer portion 11, such that side margin portions 21 cover the surfaces of the outer layer portions 22 and those of the inner layer portion 11 that are adjacent to the side surfaces B. Referring to FIG. 3, W1 denotes a width (W gap) of the side margin portion 21, and W1 is preferably about 10 μm or greater and about 30 μm or less, for example.

Each side margin portion 21 includes a single layer or a plurality of layers. Each side margin portion 21 of the present example embodiment includes two layers, namely, a side margin outer layer 21a located close to the outside and a side margin inner layer 21b located close to the internal electrode layers 15. In the case where each side margin portion 21 includes a plurality of layers, the presence of the plurality of layers can be confirmed in a dark field of an optical microscope, and can also be determined by using an additive or the like to segregate between the layers.

In the case where each side margin portion 21 includes a plurality of layers, the innermost layer may be thin and the outer layer may be thick, or inner grains may differ in grain size from outer grains. Furthermore, the denseness of the side margin outer layer 21a may be reduced by, for example, making the side margin outer layer 21a include larger grains than the side margin inner layer 21b.

In the case where each side margin portion 21 includes a single layer, the size of dielectric grains included in the side margin portion 21 may decrease from the outside to the inside in the single layer.

The side margin portions 21 may include Si in a larger amount than the dielectric layers 14. By making the side margin portions 21 include Si in a larger amount than the dielectric layers 14, Si functions as a liquid phase in the firing step S6 to be described later, whereby sintering of the ceramic included in the side margin portions 21 is promoted, and the denseness of the side margin portions 21 increases. As a result, the mechanical strength of the side margin portions 21 increases, thereby making it possible to prevent or reduce the development of a crack in the side margin portions 21. In addition, when the side margin portions 21 include Si in a larger amount than the dielectric layers 14, sintering of the ceramic is promoted in the dielectric layers 14 and in the side margin portions 21 that are adjacent to the dielectric layers 14, thereby making it possible to improve the adhesion between the side margin portions 21 and the dielectric layers 14.

### External Electrode 3

The external electrodes 3 include the first external electrode 3A provided on the first end surface C1 of the multilayer body 2 and the second external electrode 3B provided on the second end surface C2 of the multilayer body 2. The first external electrode 3A and the second external electrode 3B are collectively referred to as the external electrode(s) 3 when it is unnecessary to particularly distinguish from each other.

As described above, the end of the first lead-out portion 15Ab of each first internal electrode layer 15A is exposed at the first end surface C1 and is electrically connected to the first external electrode 3A. The end of the second lead-out portion 15Bb of each second internal electrode layer 15B is exposed at the second end surface C2 and is electrically connected to the second external electrode 3B. Thus, a plurality of capacitor elements are electrically connected in parallel between the first external electrode 3A and the second external electrode 3B.

In the present example embodiment, each external electrode 3 includes a base electrode layer 30 and a plated layer 31 on the base electrode layer 30.

### Base Electrode Layer 30

The base electrode layer 30 includes at least one layer selected from a fired layer 30a, a conductive resin layer 30b, a thin film layer 30c, or the like. In the present example embodiment, the base electrode layer 30 includes three layers, namely, the fired layer 30a, the conductive resin layer 30b, and the thin film layer 30c.

### Fired Layer 30a

The fired layer 30a includes at least one metal selected from, for example, Cu, Ni, Ag, Pd, a Ag—Pd alloy, Au, or the like. The fired layer 30a may be defined by a single layer or a plurality of layers. The fired layer 30a includes glass and the metal. In the present example embodiment, the fired layer 30a is fired simultaneously with the internal electrode layers 15, but this is a non-limiting example. The fired layer 30a may be fired after the internal electrode layers 15 are fired. The thickness of a thickest portion of the fired layer 30a is preferably about 10 μm or greater and about 30 μm or less, for example. In the case of forming the conductive resin layer 30b, the fired layer 30a may be omitted, and the conductive resin layer 30b may be formed directly on the multilayer body 2.

### Conductive Resin Layer 30b

In the present example embodiment, the conductive resin layer 30b includes conductive particles and a thermosetting resin. Specific examples of the thermosetting resin include various known thermosetting resins such as epoxy resins, phenol resins, urethane resins, silicone resins, polyimide resins, etc. As a metal component, Ag or a base metal powder having a surface coated with Ag can be used, for example. In the case of forming the conductive resin layer 30b, the fired layer 30a may be omitted, and the conductive resin layer 30b may be formed directly on the multilayer body 2. The conductive resin layer 30b may be constituted by a single layer or a plurality of layers. The thickness (of a thickest portion) of the conductive resin layer 30b is preferably about 20 μm or greater and about 40 μm or less, for example.

The conductive resin layer 30b, which includes the thermosetting resin, is more flexible than the fired layer 30a that is made of, for example, a plated film or a fired product of a conductive paste. For this reason, when a physical impact or an impact due to a thermal cycle is applied to the multilayer ceramic capacitor 1, the conductive resin layer 30b functions as a buffer layer to inhibit a crack from developing in the multilayer ceramic capacitor 1. In addition, the conductive resin layer 30b tends to absorb piezoelectric vibration, and is effective in preventing or reducing the so-called “acoustic noise”.

### Thin Film Layer 30c

The thin film layer 30c is formed by a thin film forming method such as sputtering or vapor deposition, is made of deposited metal particle, and has a thickness of about 1 μm or less, for example.

### Plated Layer 31

The plated layer 31 preferably includes, for example, plating of one type of metal selected from the group consisting of Cu, Ni, Ag, Pd, a Ag—Pd alloy, Au, or the like, or plating of an alloy including one or more types selected from the group. The plated layer 31 is preferably constituted by a plurality of layers. In the present example embodiment, the plated layer 31 includes a first plated layer 31a and a second plated layer 31b on the first plated layer 31a. In the present example embodiment, the first plated layer 31a is a Ni plated layer, and the second plated layer 31b is a Sn plated layer. The Ni plated layer 31a can prevent the base electrode layer 30 from being eroded by solder that is used when a ceramic electronic component is mounted. The Sn plated layer 31b can improve wettability of solder that is used when a ceramic electronic component is mounted, and can facilitate the mounting. The thickness per plated layer is preferably about 5 μm or greater and about 10 μm or less, for example.

Each external electrode 3 covers not only the end surface C but also portions of the main surfaces A and portions of the side surfaces B that are adjacent to the end surface C. Accordingly, each external electrode 3 includes an end surface portion 3c on the end surface C of the multilayer body 2, side surface portions 3b extending on the side surfaces B from the end surface C, and main surface portions 3a extending on the main surfaces A from the end surface C.

### Main Surface Portion 3a

As illustrated in FIG. 1, for one multilayer ceramic capacitor 1, the main surface portions 3a include a main surface portion 3al of the first external electrode 3A and provided on the first main surface A1, and a main surface portion 3a2 of the second external electrode 3B and provided on the first main surface A1.

The main surface portions 3a of one multilayer ceramic capacitor 1 further include a main surface portion of the first external electrode 3A and provided on the second main surface A2, which is a back side not shown in FIG. 1, and a main surface portion of the second external electrode 3B and provided on the second main surface A2.

In other words, one multilayer ceramic capacitor 1 includes four main surface portions 3a.

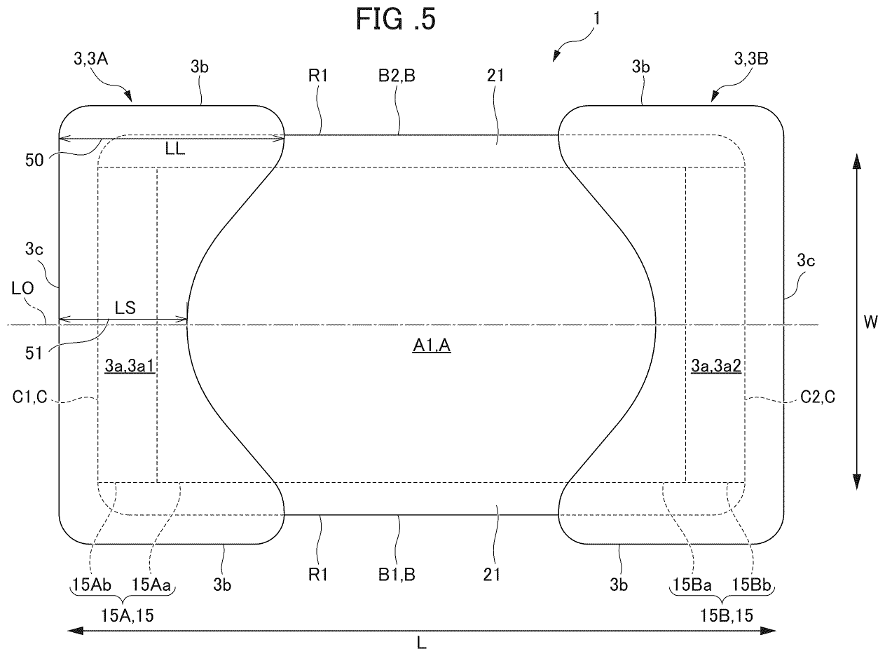

FIG. 5 is a front view of the multilayer ceramic capacitor 1 of the first example embodiment, as viewed from the first main surface A1 in the lamination direction T.

When viewed in the direction of FIG. 5, each of the four main surface portions 3a including the main surface portion 3al and the main surface portion 3a2 illustrated in FIG. 5 includes a region in which the internal electrode layers 15 are located, and two regions which are located on both sides of the region in the width direction W and in which the side margin portions 21 are located.

In the present example embodiment, the four main surface portions 3a are identical or substantially identical in shape with each other, are each axially symmetric with respect to a straight line LO passing through the center in the width direction W and extending in the length direction L, and each have a shape that is concave in a central portion in the width direction W. The main surface portion of the external electrode of the present invention is different from the main surface portion of a typical external electrode, which has a shape that is convex in a central portion in the width direction W.

### Shortest Portion 51

Since each main surface portion 3a has the shape that is concave in a central portion in the width direction W, it includes a shortest portion 51 with a shortest length LS in the length direction L, at the center in the width direction W. The shortest portion 51 is located in the region in which the internal electrodes layer 15 are located when viewed in the direction of FIG. 5.

### Longest Portion 50

Each main surface portion 3a has a length in the length direction L increasing from the shortest portion 51 with the length LS toward both sides in the width direction W, and includes longest portions 50 with a longest length LL and located in the regions in which the side margin portions 21 are located and which does not overlap with the region where the internal electrode layers 15 are located. In the present example embodiment, the longest portions 50 are each located on the ridge R1 where the main surface A and the side surface B meet each other, and which is an end of the side margin portion 21 in the width direction W.

In the present example embodiment, one main surface portion 3a includes the longest portions 50 with the equal length LL in its both end portions in the width direction W. In other words, since the four main surface portions 3a are identical or substantially identical in shape with each other and each include two longest portions 50, the multilayer ceramic capacitor 1 of the present example embodiment includes a total of eight longest portions 50.

### Method of Manufacturing Multilayer Ceramic Capacitor 1

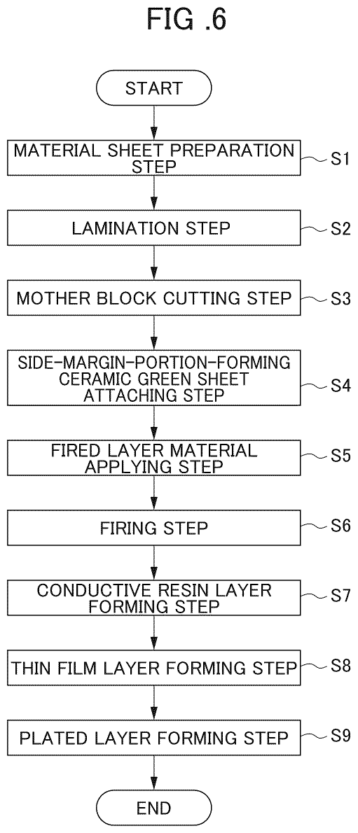

FIG. 6 is a flowchart illustrating a method of manufacturing the multilayer ceramic capacitor 1.

### Material Sheet Preparation Step S1

First, a ceramic slurry including ceramic powder, a binder, a solvent, or the like is prepared. The ceramic slurry is formed into a sheet shape on a carrier film by using a die coater, a gravure coater, a micro-gravure coater, or the like, thereby producing ceramic green sheets.

Subsequently, a conductive paste is printed into a strip-shaped conductive pattern on each of the ceramic green sheets by way of screen printing, ink jet printing, gravure printing, or the like, thereby preparing material sheets.

Similarly to the ceramic slurry, a ceramic slurry for the outer layer portions is prepared.

The ceramic slurry for the outer layer portions is formed into a sheet shape on a carrier film by using a die coater, a gravure coater, a micro-gravure coater, or the like, whereby ceramic green sheets for the outer layer portions are prepared.

### Lamination Step S2

Next, a plurality of the material sheets are laminated. In this step, the material sheets are laminated such that the strip-shaped conductive patterns are oriented in the same direction and are shifted by a half pitch in the width direction W between adjacent material sheets. Furthermore, on the upper and lower sides in the lamination direction T of the resultant laminate of the material sheets, the ceramic green sheets for the outer layer portions, which are to form the outer layer portions 22, are laminated.

Subsequently, the ceramic green sheets for the outer layer portions and the laminate of the material sheets are thermocompression-bonded to each other, whereby a mother block is produced.

### Mother Block Cutting Step S3

Next, the mother block is cut into pieces having dimensions corresponding to those of the multilayer chip 10.

Thus, a plurality of the multilayer chips 10 are produced.

### Side-Margin-Portion-Forming Ceramic Green Sheet Attaching Step S4

First, an inner-layer ceramic slurry and an outer-layer ceramic slurry are prepared.

The outer-layer ceramic slurry is applied to a surface of a carrier film and dried, and the inner-layer ceramic slurry is applied to the dried outer-layer ceramic slurry and dried, whereby ceramic green sheets having a two-layer structure are produced.

Thereafter, the ceramic green sheets are peeled off from the carrier film, and then, are each placed so that its inner-layer ceramic green sheet faces a side surface of the multilayer chip 10. Thereafter, the ceramic green sheets are pressed and punched out, whereby side-margin-portion-forming ceramic green sheets are attached to the side surfaces of the multilayer chip 10.

In contrast to the present example embodiment, according to a typical method of manufacturing a multilayer ceramic capacitor, in the material sheet preparation step S1, a conductive pattern is printed on each ceramic green sheet such that gaps to form side margin portions are left. Thus, the ceramic green sheets already including the side margin portions are laminated together. That is, the side margin portions are in advance included in the multilayer chip, and are not attached after the preparation of the multilayer chip. In the case of the typical method, the internal electrode layers may have a laminating deviation or a printing deviation in the lamination direction, and the widthwise ends of the internal electrode layers may not be aligned, thereby raising the possibility that the internal electrode layers are present in the regions of the side margin portions.

On the other hand, in the present example embodiment, when the multilayer chips 10 are cut out from the mother block in the mother block cutting step S3, the widthwise ends of the internal electrode layers 15 are cut and brought into an aligned state. The side-margin-portion-forming ceramic green sheets are attached to the side surfaces of the multilayer chip 10 on which the internal electrode layers 15 are exposed without deviation in the lamination direction T.

Therefore, in the WT cross section illustrated in FIG. 3, the positional deviation d in the width direction W is about 5 μm or less, for example, between the widthwise ends of two adjacent internal electrodes, i.e., one first internal electrode layer 15A and one second internal electrode layer 15B that are vertically adjacent to each other in the lamination direction T. That is, the widthwise end of each first internal electrode layer 15A and that of the second internal electrode layer 15B vertically adjacent to the first internal electrode layer 15A in the lamination direction T are substantially at the same position in the width direction W, and are substantially aligned with each other in the lamination direction T.

Therefore, even if a crack develops in the main surface A on the side margin portion 21 and extends in the lamination direction T, since the side margin portion 21 does not have the internal electrode layers 15 arranged therein, the possibility that the crack reaches the internal electrode layers 15 is reduced.

### Fired Layer Material Applying Step S5

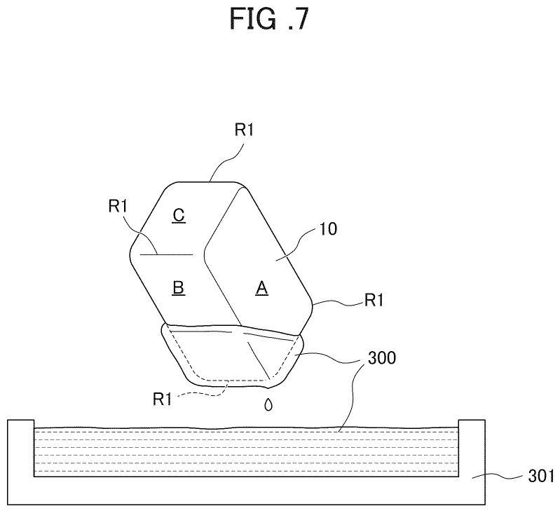

A material for the fired layer 30a is attached to both end surfaces C of the multilayer chip 10 having side-margin-portion-forming ceramic green sheets attached thereto. FIG. 7 is a diagram for explaining an example of the fired layer material applying step S5 as a process for forming the external electrodes 3.

As illustrated, a portion of the multilayer body 2 including one ridge R1 where the side surface B and the end surface C meet each other and the vicinity of the one ridge R1 is dipped into a liquid 300 that is the material for the fired layer 30a. The multilayer body 2 includes four ridges R1 where the side surface B and the end surface C meet each other, and the four ridges R1 and the vicinities thereof are sequentially dipped. In this way, the material for the fired layer 30a is applied in a shape that is axially symmetric with respect to the straight line passing through the center in the width direction W and extending in the length direction L, and have a shape that is concave in a central portion in the width direction W, as illustrated in FIG. 1.

### Firing Step S6

The multilayer body 2 including the material for the fired layer 30a attached thereto is degreased under a predetermined condition in a nitrogen atmosphere, and then fired at a predetermined temperature in a nitrogen-hydrogen-water vapor atmosphere, thereby forming the fired layers 30a.

### Conductive Resin Layer Forming Step S7

Next, a material that is to form the conductive resin layer 30b and includes conductive particles and a thermosetting resin is attached to the fired layers 30a.

### Thin Film Layer Forming Step S8

Furthermore, the thin film layer 30c including deposited metal particles is formed on the material for the conductive resin layer 30b on the multilayer body 2.

### Plated Layer Forming Step S9

Subsequently, as the plated layer 31, the first plated layer 31a that is a Ni plated layer and the second plated layer 31b that is a Sn plated layer are formed such that the second plated layer 31b extends on the first plated layer 31a.

### Method of Mounting Multilayer Ceramic Capacitor

The multilayer ceramic capacitor 1 manufactured through the above-described steps is mounted on a board. At this time, one of the main surfaces A of the multilayer ceramic capacitor 1 defines and functions as a mounting surface to be mounted on the board.

### Advantageous Effects of Multilayer Ceramic Capacitor 1 of the Present Example Embodiment

The multilayer ceramic capacitor 1 includes the outer layer portions 22 and the side margin portions 21, which are all thin. When a bending force is applied to the board on which the multilayer ceramic capacitor 1 having this configuration is mounted, the main surface A of the multilayer ceramic capacitor 1 is likely to bend together with the board.

Here, in contrast to the present example embodiment, the external electrodes of a typical multilayer ceramic capacitor have a shape in which the longest portion of the main surface portion is at the center in the width direction W, and the central portion protrudes toward the opposite end surface.

In the case of the typical multilayer ceramic capacitor, the leading end of the longest portion is located at the center in the width direction W, and thus, in a region overlapping with the region in which the internal electrode layers are located. When the main surface of the multilayer ceramic capacitor is bent, stress is likely to concentrate on the leading end of the longest portion, and accordingly, in the multilayer ceramic capacitor, a crack is likely to develop in the outer layer portion 22 adjacent to the main surface where the leading end of the longest portion is located. In this situation, the crack may penetrate the thin outer layer portion 22 to reach the internal electrode layers 15 in the inner layer portion 11, and moisture may infiltrate to the internal electrode layers 15 through the crack to cause a defect such as a short circuit.

On the other hand, in the present example embodiment, the longest portions 50 that are longer in the length direction L than the rest of the main surface portion 3a of the external electrode 3 are provided on the side margin portions 21, and more specifically, are located on the ridges R1 at which the main surface A and the side surface B meet each other and which is in the side margin portions 21.

That is, when the multilayer ceramic capacitor 1 is viewed from the main surface A in the lamination direction T, the leading ends of the longest portions 50 are each located in a region that does not overlap with the region where the internal electrode layers 15 are located.

Therefore, in a case where the main surface A of the multilayer ceramic capacitor 1 is bent, even if stress concentrates on the leading end of the longest portion 50 and a crack develops, the location where the crack has developed is in the side margin portion 21 in which the internal electrode layers 15 are not present. Therefore, even if the crack extends to the interior, the crack does not reach the internal electrode layers 15, and moisture is prevented from infiltrating to the internal electrode layers 15, so that the possibility of a defect such a short circuit is reduced.

Furthermore, in a case where, in the side margin portion 21, the denseness of the side margin outer layer 21a is reduced by, for example, making the side margin outer layer 21a include larger grains than the side margin inner layer 21b, a crack is more likely to develop at the leading end of the longest portion 50 located on the side margin portion 21. Therefore, in this case, the possibility of development of a crack in the portion in which the internal electrode layers 15 are present is further reduced.

Furthermore, by making the side margin portions 21 include Si in a larger amount than the dielectric layers 14, Si functions as a liquid phase in the firing step S6, whereby sintering of the ceramic included in the side margin portions 21 is promoted, and the denseness of the side margin portions 21 increases. As a result, the mechanical strength of the side margin portions 21 increases, thus making it possible to prevent or reduce the development of a crack in the side margin portions 21. In addition, the feature in which the side margin portions 21 include Si in a larger amount than the dielectric layers 14 promotes sintering of the ceramic in the dielectric layers 14 and in the side margin portions 21 that are adjacent to the dielectric layers 14, thus making it possible to improve the adhesion between the side margin portions 21 and the dielectric layers 14.

### Second Example Embodiment

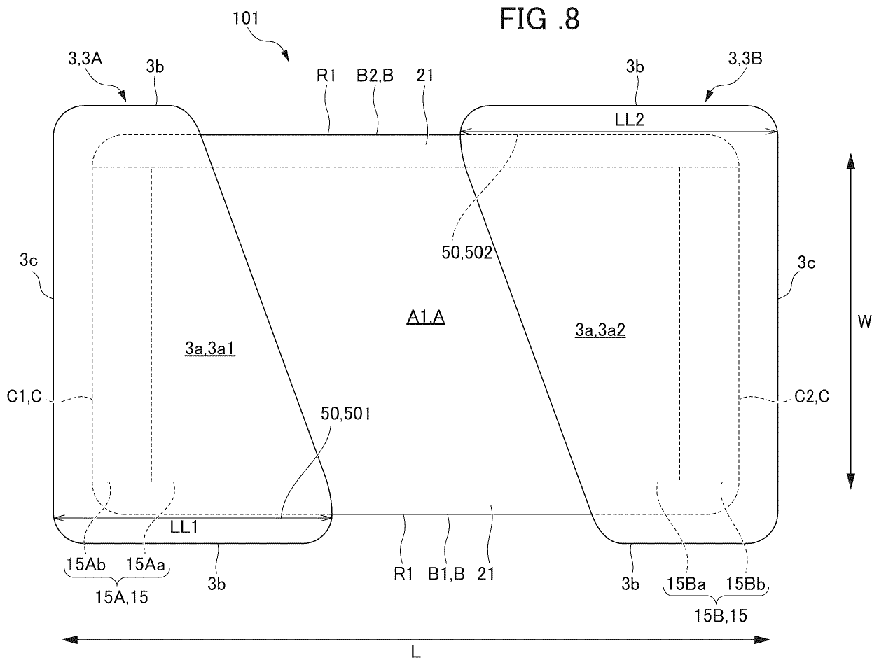

Next, a second example embodiment of the present invention will be described. FIG. 8 is a front view of a multilayer ceramic capacitor 101 of the second example embodiment as viewed from the first main surface A1 in the lamination direction T.

The multilayer ceramic capacitor 101 of the second example embodiment is different from the multilayer ceramic capacitor of the first example embodiment in that main surface portions 3a of the second example embodiment have a trapezoidal shape, instead of the concave shape in a central portion in the width direction W. The same components as those of the first example embodiment are denoted by the same reference signs, and description thereof is omitted.

The main surface portion 3al of the first external electrode 3A and provided on the first main surface A1 and the main surface portion (not shown) of the first external electrode 3A and provided on the second main surface A2 have the same trapezoidal shape. The main surface portion 3a2 of the second external electrode 3B and provided on the first main surface A1 and the main surface portion (not shown) of the second external electrode 3B and provided on the second main surface A2 have the same trapezoidal shape, which is different from the trapezoidal shape of the main surface portion 3al.

Here, a shorter side and a longer side of the trapezoidal shape that are parallel or substantially parallel to each other are referred to as an upper base and lower base, respectively. The lower base of the main surface portion 3al is located on a portion of the first main surface A1 adjacent to the first side surface B1, and a longest portion 501 (50) with a length LL1 is on the ridge R1 where the first main surface A1 meets the first side surface B1.

The lower base of the main surface portion 3a2 is located on a portion of the first main surface A1 adjacent to the second side surface B2, and a longest portion 502 (50) with a length LL2 is on the ridge R1 where the first main surface A1 meets the second side surface B2.

That is, in the second example embodiment, each main surface portion 3a includes one longest portion 50.

The length LL1 of the longest portion 501 of the main surface portion 3al is different from the length LL2 of the longest portion 502 of the main surface portion 3a2, and LL1<LL2 is satisfied.

Unlike the first example embodiment, each main surface portion 3a of the second example embodiment includes one longest portion 50. The main surface portions 3a at the four locations are not identical in shape with each other. In addition, the lengths of the longest portions 50 of the main surface portions 3a are not all the same.

However, also in the second example embodiment, when the multilayer ceramic capacitor 101 is viewed from the main surface, the longest portions 50 of the main surface portions 3a are located on regions that do not overlap with the regions in which the internal electrode layers 15 are located.

Therefore, as in the first example embodiment, in a case where the main surface A of the multilayer ceramic capacitor 1 is bent, even if stress concentrates on the leading end of the longest portion 50 and a crack develops, the location where the crack has developed is in the side margin portion 21 in which the internal electrode layers 15 are not present. Therefore, even if the crack extends to the interior, the crack does not reach the internal electrode layers 15, and moisture is prevented from infiltrating to the internal electrode layers 15, so that the possibility of a defect such a short circuit is reduced.

It should be noted that the present invention is not limited to the first and second example embodiments described above. The longest portions of the main surface portions are not limited to those described in the above example embodiments, and can be variously modified as long as the longest portions are each located on a region not overlapping with the region in which the internal electrode layers are located when the multilayer ceramic capacitor is viewed from the main surface.
(1) As in the first example embodiment, each main surface portion 3a may include longest portions 50 extending on two or more locations. As in the second example embodiment, each main surface portion 3a may include one longest portion 50. The main surface portions 3a provided at four locations do not have to be identical in shape with each other. The longest portions 50 of the main surface portions 3a may have different lengths.
(2) In the first example embodiment, the multilayer ceramic capacitor 1 includes the side margin portions 21 attached to both sides of the multilayer chip. However, the present invention is not limited to this configuration.

For example, the side margin portions may be formed in the following way. In the material sheet preparation step S1, a conductive pattern is printed on each ceramic green sheet such that gaps for the side margin portions are left, and a ceramic slurry for absorbing level difference is further applied to the gaps, so that the side margin portions include portions in which the ceramic green sheets and the ceramic slurry for absorbing level differences are laminated.

In this case, a ceramic slurry that will have, in a sintered state, a higher mechanical strength than the ceramic green sheets may be used as the ceramic slurry for absorbing level differences. For example, a ceramic slurry including Si will have a high mechanical strength increasing through sintering. Si included in the ceramic slurry functions as a liquid phase in the firing step S6, whereby sintering of the ceramic in the side margin portions 21 is promoted, and the denseness of the side margin portions 21 increases. As a result, the mechanical strength of the side margin portions 21 increases, thus making it possible to prevent or reduce the development of a crack in the side margin portions 21. In addition, when the side margin portions 21 include Si in a larger amount than the dielectric layers 14, sintering of the ceramic is promoted in the dielectric layers 14 and in the side margin portions 21 that are adjacent to the dielectric layers 14, thus making it possible to improve the adhesion between the side margin portions 21 and the dielectric layers 14.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer ceramic capacitor comprising:
a multilayer body including dielectric layers and internal electrode layers alternately laminated, and including main surfaces on both sides in a lamination direction, side surfaces on both sides in a width direction that is orthogonal to the lamination direction, and end surfaces on both sides in a length direction that intersects with the lamination direction and the width direction; and
external electrodes respectively provided on the end surfaces and each including an end surface portion on the end surface where the external electrode is provided, main surface portions respectively extending on the main surfaces in the length direction from the end surface toward an other end surface, and side surface portions respectively extending on the side surfaces in the length direction from the end surface toward the other end surface; wherein
each of the main surface portions includes a longest portion that is longer in the length direction than a remainder of the main surface portion, and when the multilayer ceramic capacitor is viewed from the main surface, the longest portion is located on a region that does not overlap with a region in which the internal electrode layers are located.

2. The multilayer ceramic capacitor according to claim 1, wherein the longest portion is located on a ridge where the main surface meets the side surface.

3. The multilayer ceramic capacitor according to claim 1, wherein each of the main surface portions includes a shortest portion that is shorter in the length direction than a remainder of the main surface portion and is located in a central portion of the main surface in the width direction.

4. The multilayer ceramic capacitor according to claim 1,
wherein two of the internal electrode layers that are adjacent to each other in the lamination direction have widthwise ends with a positional deviation of about 5 μm or less in the width direction.

5. The multilayer ceramic capacitor according to claim 1, wherein the multilayer body includes an inner layer portion in which the dielectric layers and the internal electrode layers are alternately laminated, and side margin portions provided on both sides of the inner layer portion in the width direction, and the side margin portions include Si in a larger amount than the dielectric layers.

6. The multilayer ceramic capacitor according to claim 1, wherein dimensions of the multilayer capacitor are about 0.2 mm or greater and about 2.0 mm or less in the length direction, about 0.1 mm or greater and about 1.0 mm or less in the width direction, and about 0.1 mm or greater and about 0.5 mm or less in the lamination direction.

7. The multilayer ceramic capacitor according to claim 1, wherein the multilayer body has a substantially rectangular parallelepiped shape.

8. The multilayer ceramic capacitor according to claim 1, wherein each of the external electrodes includes a base electrode layer and a plated layer.

9. The multilayer ceramic capacitor according to claim 8, wherein the base electrode layer includes at least one of a fired layer, a conductive layer resin, and a thin film layer.

10. The multilayer ceramic capacitor according to claim 1, wherein each of the main surface portions has a concave shaped central portion in the width direction.

11. The multilayer ceramic capacitor according to claim 10, wherein each of the main surface portions includes a shortest portion that is shorter in the length direction than a remainder of the main surface portion and is located in the concave shaped central portion.

12. The multilayer ceramic capacitor according to claim 1, wherein each of the main surface portions has a trapezoidal shaped central portion in the width direction.

13. The multilayer ceramic capacitor according to claim 12, wherein each of the main surface portions includes a shortest portion that is shorter in the length direction than a remainder of the main surface portion and is located in the concave shaped central portion.

14. The multilayer ceramic capacitor according to claim 12, wherein the main surface portions have a same trapezoidal shape of the trapezoidal shaped central portions.

15. The multilayer ceramic capacitor according to claim 12, wherein a trapezoidal shape of the trapezoidal shaped central portions of some of the main surface portions differ from each other.

16. The multilayer ceramic capacitor according to claim 1, wherein the multilayer body includes eight of the longest portions.

17. The multilayer ceramic capacitor according to claim 1, wherein each of the main surface portions includes only one of the longest portion.

18. The multilayer ceramic capacitor according to claim 1, wherein a length of the longest portion of a first one of the main surface portions is not equal to a length of the longest portion of a second one of the main surface portions.

19. The multilayer ceramic capacitor according to claim 1, wherein shapes of the main surface portions are not identical.

20. A method of mounting the multilayer ceramic capacitor according to claim 1, the method comprising:
placing the multilayer ceramic capacitor such that one of the main surfaces defines and functions as a mounting surface.
